(19) United States
(12) Patent Application Publication
(10) Pub. No.: US 2017/0263502 A1
(43) Pub. Date: Sep. 14, 2017

(54) METHOD FOR MANUFACTURING ELEMENT CHIP

(71) Applicant: Panasonic Intellectual Property Management Co., Ltd., Osaka (JP)

(72) Inventors: SHOGO OKITA, Hyogo (JP); ATSUSHI HARIKAI, Osaka (JP); AKIHIRO ITOU, Kyoto (JP); NORIYUKI MATSUBARA, Osaka (JP); BUNZI MIZUNO, Nara (JP)

(21) Appl. No.: 15/428,477

(22) Filed: Feb. 9, 2017

(30) Foreign Application Priority Data
Mar. 9, 2016 (JP) 2016-046344

(51) Int. Cl. H01L 21/78; H01L 21/3065; H01L 21/683; H01L 21/311; H01L 21/67

(52) U.S. Cl. CPC H01L 21/78; H01L 21/31116; H01L 21/67069; H01L 21/6833; H01L 21/3065

(57) ABSTRACT

The method for manufacturing an element chip includes a mounting step and a plasma dicing step. In the mounting step, a semiconductor substrate with flexibility, which has a first main surface and a second main surface located at an opposite side of the first main surface, which has a plurality element regions and a dividing region for defining the element regions, and on which a mask for covering the first main surface in the element region and for exposing the first main surface in the dividing region is formed, is mounted on a stage. In the plasma dicing step, the semiconductor substrate is diced into a plurality of element chips including the element; region by exposing the first main surface side of the semiconductor substrate to plasma on the stage and etching from the first main surface side to the second main surface while forming a groove on the dividing region.

### BACKGROUND

1. Technical Field

The present disclosure relates to a method for manufacturing an element chip without a scallop (step), which is formed by repeating etching and stacking of a protective film, on a side surface.

2. Description of the Related Art

In the related art, in a plasma process, when the element chip which is obtained by dicing a semiconductor substrate through a plasma etching is manufactured, a so-called Bosch method (also referred to as a TDM method) capable of deep digging is adopted (for example, PTL 1). In the process, a step of stacking the protective film on a surface of the semiconductor substrate which is held on a holding sheet such as a dicing tape and a step of plasma etching the semiconductor substrate in a region where the protective film is removed are repeated in plural times in this order.

FIG. 5 is a schematic cross-sectional view schematically illustrating a dicing procedure by the Bosch method, in the Bosch method, firstly, mask 301 is formed on one main surface (first main surface) of semiconductor substrate 303 on which the other main surface (second main surface) is held on adhesive layer 302a on base layer 302b of holding sheet 302 (a). Mask 301 is formed so as to cover a plurality of elements included in the first main surface of semiconductor substrate 303 and expose a dividing region for dividing plurality of element regions. Groove 304 is formed by etching the dividing region from the first main surface side through isotropic plasma etching (b). Protective film 305 is formed on the first main surface side by plasma CVD (c) and protective film 305 is mainly removed from a bottom portion of groove 304 through anisotropic plasma etching (d). By further performing the isotropic plasma etching, groove 304 is bored in a depth direction (e). By sequentially repeating (c), (d), and (e), groove 304 is bored from the first main surface side to the second main surface. Accordingly, the dividing region is removed and the semiconductor substrate is diced. Therefore, the element chip including the element region is obtained (f).

In this manner, in the Bosch method, boring in the depth direction is performed by repeating the formation of protective film 305 on a front surface (including also a front surface of the groove) of the semiconductor substrate, the removal of protective film 305 at the bottom of groove 304, and the isotropic plasma etching. Since the etching progresses also in a horizontal direction when the boring in the depth direction is performed through the isotropic plasma etching, if the formation of protective film 305, the removal of protective film 305, and the and isotropic plasma etching are repeated, an irregularity (scallop S) is naturally formed on a side wall of groove 304 (that is, a side surface of element chip 306) as illustrated in FIG. 5.

### CITATION LIST

### Patent Literature

PTL 1: Japanese Patent Unexamined Publication No. 2014-513868

### SUMMARY

In the Bosch method, it is difficult to remove a scallop. If the scallop is present, there is a case where a crack may occur in the element chip starting from the scallop.

An object of the present disclosure is to provide a method for manufacturing an element chip which is hard to crack during transporting or picking up the element chip.

An aspect of the present disclosure relates to a method for manufacturing an element chip to be described below. That is, the aspect relates to a method for manufacturing an element chip including a mounting step of mounting a semiconductor substrate on a stage included in a plasma processing apparatus and a plasma dicing step. The semiconductor substrate with flexibility has a first main surface and a second main surface located at an opposite side of the first main surface and has a plurality element regions and a dividing region for defining the element regions, on which a mask for covering the first main surface in each of the element regions and for exposing the first main surface in the dividing region is formed. In the mounting step, the semiconductor substrate is mounted on the stage included in the plasma processing apparatus, in a state where the second main surface is held on a holding sheet.

In the plasma dicing step, by exposing a side of the first main surface of the semiconductor substrate to plasma and by etching the semiconductor substrate from the side of the first main surface to the second main surface while forming a groove on the dividing region, the semiconductor substrate is diced into a plurality of element chips including the element regions.

In addition, a thickness of the semiconductor substrate is smaller than a thickness of the holding sheet.

In addition, in the plasma dicing step, by performing the etching the semiconductor substrate from the side of the first main surface to the second main surface in a state where a bottom portion of the groove is always exposed, the semiconductor substrate is diced without forming a scallop on a side surface of each of the element chips.

According to the method for manufacturing an element chip of the present disclosure, the element chip is hardly cracked when the element chip which is held on the holding sheet is transported or the element chip is picked up from the holding sheet.

### BRIEF DESCRIPTION OF THE DRAWINGS

FIG. 1A is a top surface view illustrating a semiconductor substrate in a state where the semiconductor substrate is held on a holding sheet to be used in an exemplary embodiment of the present disclosure;

FIG. 1.B is a cross-sectional view-taken along line IB-IB of FIG. 1A;

FIG. 2 is a schematic cross-sectional view schematically illustrating a method for manufacturing an element chip according to the exemplary embodiment of the present disclosure;

FIG. 3 is a schematic cross-sectional view schematically illustrating a state where dicing progresses in a plasma dicing step according to the exemplary embodiment of the present disclosure;

FIG. 4 is a schematic cross-sectional view schematically illustrating a structure of a plasma processing apparatus to be used in the method for manufacturing an element chip according to the exemplary embodiment of the present disclosure;

FIG. 5 is a schematic cross-sectional view schematically illustrating a procedure of the dicing by a conventional Bosch method;

FIG. 6A is a schematic cross-sectional view schematically illustrating a state of an element chip when a thick element chip having a scallop on a side surface is picked up from the holding sheet;

FIG. 6B is a schematic cross-sectional view schematically illustrating a state of the element chip when the thick element chip having the scallop on the side surface is picked up from the holding sheet;

FIG. 6C is a schematic cross-sectional view schematically illustrating a state of the element chip when the thick element chip having the scallop on the side surface is picked up from the holding sheet;

FIG. 7A is a schematic cross-sectional view schematically illustrating a state of the element chip when a thin element chip having the scallop on the side surface is picked up from the holding sheet;

FIG. 7B is a schematic cross-sectional view schematically illustrating a state of the element chip when the thin element chip having the scallop on the side surface is picked up from the holding sheet;

FIG. 7C is a schematic cross-sectional view schematically illustrating a state of the element chip when the thin element chip having the scallop on the side surface is picked up from the holding sheet;

FIG. 7D is a schematic cross-sectional view schematically illustrating a state of the element chip when the thin element chip having the scallop on the side surface is picked up from the holding sheet;

FIG. 8A is a schematic cross-sectional view schematically illustrating a state of the element chip when the thin element chip according to the exemplary embodiment of the present disclosure is picked up from the holding Sheet;

FIG. 8B is a schematic cross-sectional view schematically illustrating a state of the element chip when the thin element chip according to the exemplary embodiment of the present disclosure is picked up from the holding sheet;

FIG. 8C is a schematic cross-sectional view schematically illustrating a state of the element chip when the thin element chip according to the exemplary embodiment of the present disclosure is picked up from the holding sheet; and

FIG. 8D is a schematic cross-sectional view schematically illustrating a state of the element chip when the thin element chip according to the exemplary embodiment of the present disclosure is picked up from the holding sheet.

### DETAILED DESCRIPTION

Before describing a method for manufacturing an element chip according to the present disclosure, a problem in the method for manufacturing an element chip having a scallop and the device will be described below.

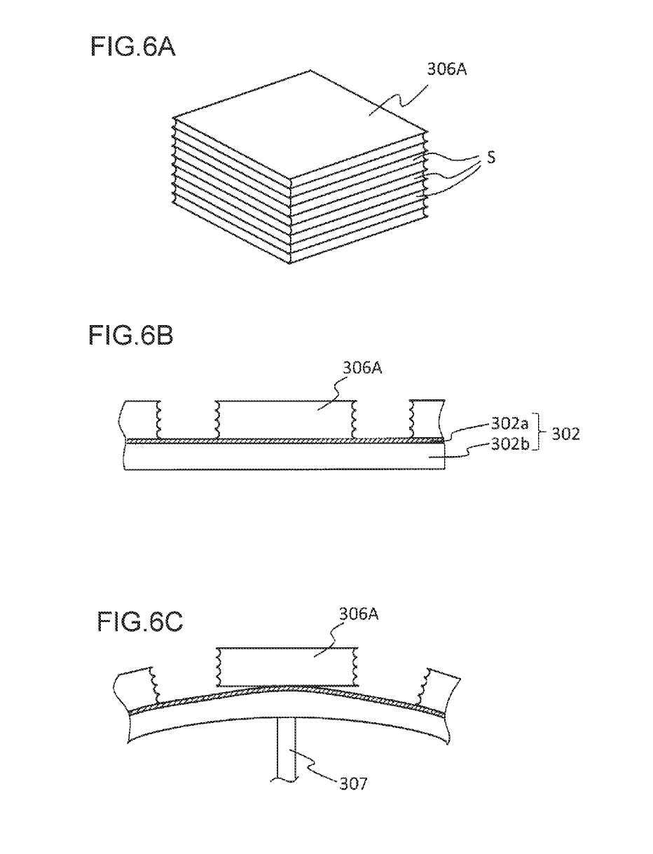

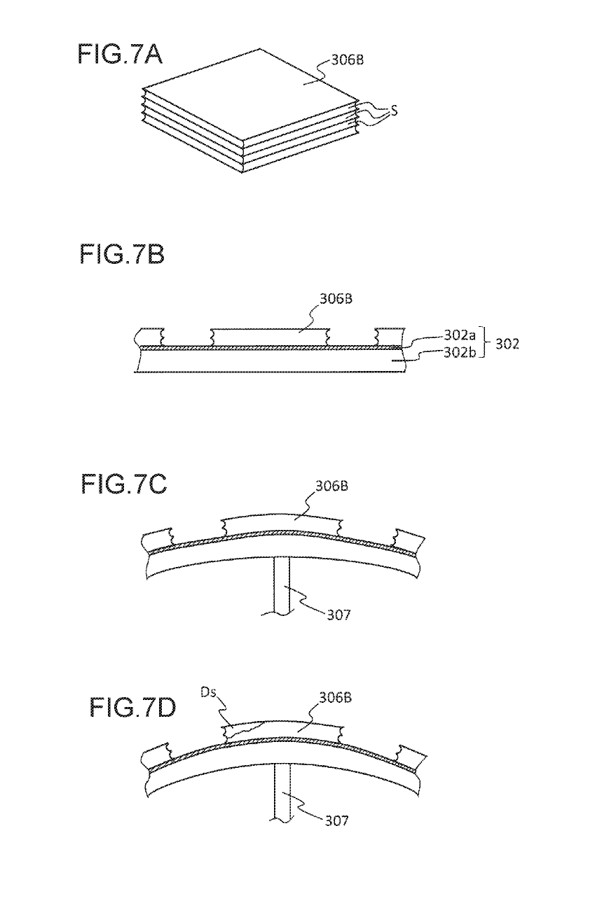

Perspective views of diced element chip 306 (306A and 306B) with scallop S are illustrated in FIGS. 6A and 7A, respectively Element chip 300 is picked up from a plasma processing apparatus in a state where element chip 306 is held on holding sheet 302 and transported to a picking up process. Since holding sheet 302 has flexibility, holding sheet 302 may bend during transportation. If element chip 306 is thick, bending of element chip 306 hardly occurs, even when holding sheet 302 is bent. If element chip 306 becomes thinner, when holding sheet 302 is bent, bending of element chip 306 easily occurs.

FIG. 6B is a schematic cross-sectional view schematically illustrating a state of element chip 306 when relatively thick element chip 306A having scallop S on the side surface is picked up from holding sheet 302. FIG. 7B is a schematic cross-sectional view schematically illustrating a state of element chip 306 when relatively thin element chip 306B having scallop S on the side surface is picked up from holding sheet 302.

In a case where element chips 306A and 306B are picked up, firstly, adhesive layer 302a is cured by irradiating adhesive layer 302a of holding sheet 302 having adhesive layer 302a and base layer 302b with an ultraviolet lay, and adhesion between holding sheet 302 and element chips 306A and 306B is reduced. By applying tension to holding sheet 302, a gap between adjacent element chips is expanded, and a region where element chips 306A and 306B of holding sheet 302 is held is pushed up with push.-up jig 307 (FIGS. 6C and 7C). Top surfaces of pushed up element chips 306A and 306B is sucked by a suction nozzle, and element chips 306A and 306B are peeled off from adhesive layer 302a of holding sheet 302.

When element chips 306A and 306B are pushed up, holding sheet 302 with flexibility is bent. In this time, by adhesion remained between holding sheet 302 and element chips 306A and 306B, stress is applied to element chips 306A and 306B.

In a case of relatively thick element chip 306A, when element chip 306 is pushed up through holding sheet 302, even if holding sheet 302 is bent as illustrated in FIG. 6C, since element chip 306 has rigidity, element chip 306A is rarely bent. Accordingly, element chip 306A is sequentially peeled off from holding sheet 302 from outer edge portion thereof toward the inner side.

On the other hand, as illustrated in FIG. 7A, in a case of relatively thin element; chip 306B, since the rigidity of element chip 306B is poor, when element chip 306B is pushed up through holding sheet 302, a great bending occurs also in element chip 306B as illustrated in FIG. 7C, and cracks and chips Ds easily occur starting from scallop S on the side surface as illustrated in FIG. 7D.

In the Bosch method, by controlling a condition of dicing, a size of scallop S can be reduced. However, it is difficult to remove scallop S. In a case of a thin element chip, when the element chip is bent when transportation or picking up, there is a case where the crack occurs in element chip starting from the scallop.

Hereinafter, the method for manufacturing an element chip according to an exemplary embodiment of the present disclosure will be described.

The method for manufacturing an element chip according to an exemplary embodiment of the present disclosure includes (1) a mounting step and (2) a plasma dicing step.

### (1) Mounting Step

In the mounting step the semiconductor substrate is mounted on a stage included in a plasma processing apparatus. The semiconductor substrate with flexibility has a first main surface and a second main surface located at an opposite side of the first main surface and has a plurality of element regions and a dividing region for defining the element region, on which a mask for covering the first main surface in the element region and exposing the first main surface in the dividing region is formed. The semiconductor substrate is mounted on the stage included in the plasma processing apparatus, in a case where the second main surface is held on the holding sheet.

### (2). Plasma Dicing Step

In the plasma dicing step, by exposing the first main surface side of the semiconductor substrate to plasma and by etching from the first main surface side to the second main surface while forming a groove on the dividing region, the semiconductor substrate is diced into a plurality of element chips including the element region.

Here, the thickness of the semiconductor substrate is smaller than the thickness of the holding sheet, in the plasma dicing step (2), by performing etching from the first main surface side to the second main surface, in a state where the bottom portion of the groove is always exposed, the semiconductor substrate is diced without forming the scallop on the side surface of the element chip. In the plasma dicing step (2), for example, the plasma may be generated using a process gas containing sulfur hexafluoride and oxygen, as a raw material.

In the present exemplary embodiment, in the plasma dicing step (2), since the plasma etching is performed in a state where the bottom portion of the groove is exposed, the scallop is not formed on the side surface of the element chip. Accordingly, when the thickness of the semiconductor substrate is smaller than the thickness of the holding sheet and the element chip is picked up from the holding sheet, the cracks or clips starting from an irregularity in the element chip side surface can be suppressed even if the element chip is bent.

Performing the plasma etching in a state where the bottom of the groove is always exposed means that the plasma etching (plasma dicing) is not performed by the Bosch method. That is, in the present exemplary embodiment, in the plasma etching method (specifically, during etching the dividing region from the first main surface of the semiconductor substrate to the second main surface), the etching is progressed without forming the protective film on the bottom portion of the groove.

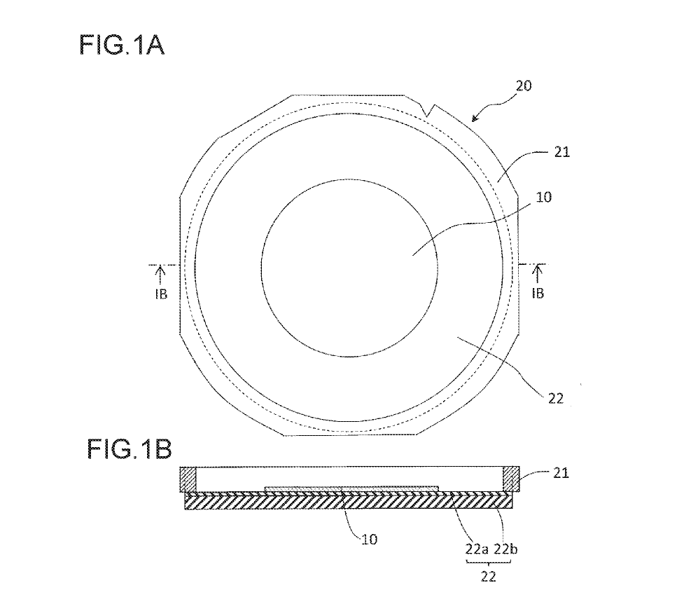

The manufacturing method according to the disclosure will be described in detail below with reference to FIGS. 1A to 4.

The semiconductor substrate to be mounted on the stage included in the plasma processing apparatus is mounted on the stage included in the plasma processing apparatus. FIG. 1A is a top surface view illustrating the semiconductor substrate in a state where the semiconductor substrate is held on the holding sheet. In addition, FIG. 1B is a cross-sectional view taken along line IB-IB of FIG. 1A. Holding sheet 22 includes adhesion layer 22a and base layer 22b for supporting adhesion layer 22a. Holding sheet 22 holds semiconductor substrate 10 by a front surface (adhesive surface) of adhesion layer 22a located at an opposite side of base layer 22b and is fixed to annular frame 21 to be disposed around semiconductor substrate 10. Frame 21 and holding sheet 22 fixed to frame 21 are collectively referred to as transfer carrier 20. Frame 21 has rigidity, and holding sheet 22 has flexibility. Accordingly, frame 21 and holding sheet 22 are elastically extensible.

Semiconductor substrate 10 includes a second main surface to be held on holding sheet 22 and a first main surface located at an opposite side of the second surface. The mask is formed on the first main surface of semiconductor substrate 10. However, the mask is omitted in FIG. 1. Although a case where frame 21 and semiconductor substrate 10 are substantially circular is illustrated in FIG. 1, the disclosure is not limited to the case.

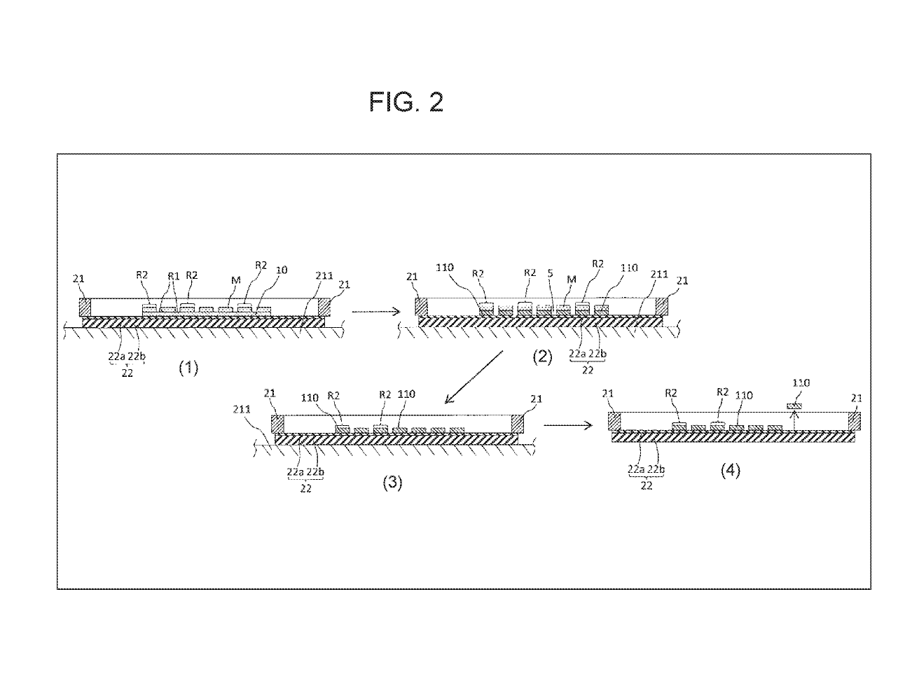

FIG. 2 is a schematic cross-sectional view schematically illustrating the method for manufacturing the element chip according to the exemplary embodiment of the disclosure. The manufacturing method of FIG. 2 includes the mounting step (1) of mounting the semiconductor substrate on which the mask is formed on the stage and the plasma dicing step (2) of etching the semiconductor substrate in the dividing region and dicing (dividing) the semiconductor substrate into the element chip. The manufacturing method of FIG. 2 further includes an aching step (3) of removing the mask and a separation (picking up) step (4) of separating the element chip from the holding sheet, after the plasma dicing step (2). In addition, prior to the mounting step (1), a preparation step of preparing the semiconductor substrate on which the mask is formed, a grinding step of grinding the semiconductor substrate, a holding step of holding the semiconductor substrate to the holding sheet, and the like are generally performed.

Hereinafter, each step will be described in detail.

### (Preparation Step of Semiconductor Substrate)

In the preparation step of the semiconductor substrate, semiconductor substrate 10 on which mask M is formed is prepared.

### (Semiconductor Substrate)

Semiconductor substrate 10 includes a plurality of element regions R2 and dividing region R1 for defining the plurality of element region R2. Mask M for covering the first main surface in element region R2 and exposing the first main surface in dividing region R1 is formed on the first main surface of semiconductor substrate 10.

Semiconductor substrate 10 is to be subjected to a plasma process and is separated into dividing region R1 and the plurality of element regions R2 which are defined by dividing region R1. A semiconductor circuit, an electric component element, and a circuit layer such as MEMS (which are not illustrated) may be formed on the front surface of element regions 112. That is, semiconductor substrate 10 may include a main body layer (or a semiconductor layer) which is formed of a semiconductor and the circuit layer. By etching dividing region R1 of semiconductor substrate 10 in the plasma dicing step (2) to be described, element chip 110 including element regions R2 is obtained.

Examples of the semiconductor configuring (the semiconductor layer of) the semiconductor substrate include silicon (Si), gallium arsenide (GaAs), gallium nitride (GaN), silicon carbide (SiC), or the like. The circuit layer includes at least insulating layer. In addition to this, the circuit layer may include a metal layer, a resin protective layer, a resist layer, an electrode pad, a bump, or the like. The insulating layer may be included as a laminate (multilayer wiring layer) with the metal material for wiring. For example, the insulating layer includes silicon dioxide (SiO₂), silicon nitride (Si₃N₄), a low dielectric constant film (Low·k film), a resin film such as polyimide, lithium tantalate (LiTaO₃), lithium niobate (LiNbO₃), or the like.

The size of semiconductor substrate 10 is not particularly limited. For example, the size thereof is about 50 mm to 300 mm in maximum diameter. The shape of semiconductor substrate 10 is also not particularly limited. For example, the shape thereof is circular or rectangular shape.

The thickness of the insulating layer or the multilayer wiring layer is not particularly limited and is within a range of 2 to 10 μm inclusive. The thickness of the resist layer is not particularly not limited, for example, is within a range of 5 to 20 μm inclusive.

In addition, an orientation flat and a cutout such as notch (Which are not illustrated) may be provided on semiconductor substrate 10.

Furthermore, a back metal layer may be disposed at an opposite side of the circuit layer of the semiconductor layer. The back metal layer is disposed in a case where element chip 110 to be obtained is a power device. For example, the back metal layer includes gold (Au), nickel (Ni), titanium (Ti), aluminum (Al), tin (Sn), silver (Ag), platinum (Pt), palladium (Pd), or the like. These materials may be used singly or in combination of two or more materials. The back metal layer may be, for example, a single layer including the above metal singly and may be the laminate of the layer including the above metal singly. The thickness of the back metal layer is not particularly not limited, for example, is within a range of 0.5 to 1.5 μm inclusive.

(M ask)

As mask M for covering element regions R2 of semiconductor substrate 10, a resist, a SiO₂ film, a silicon nitride film, a metal thin film, or the like can be used. Mask M is formed on the first main surface of semiconductor substrate 10 by a well-known method depending on the types of the configuration material.

For example, in a case of a resist mask, after forming the resist film on the front surface of semiconductor substrate 10 by a spin coat method or the like, mask M can be formed by exposing and developing the resist film. In addition, instead of the normal resist, by applying photosensitive polysiloxane or photosensitive polyimide containing a filler by the spin coat method, and exposing and developing the front surface, mask M may be formed. In this case, the resist mask containing an inorganic component such as SiO₂ can be formed.

In addition, in a case of a SiO₂ mask, firstly an SiO2 thin film is formed on the front surface of semiconductor substrate 10 by a vapor phase method such as a CVD method. Next, the resist film having an opening on a portion corresponding to the groove is formed on the SiO₂ thin film by photolithography. By etching the SiO₂ film of an opening of the resist film, the SiO₂ mask having an opening on a position corresponding to the groove is formed by etching the SiO₂ film of the opening of the resist film. The etching of the SiO₂ film can be performed by dry etching. After etching of the SiO₂ film, the resist film remaining on the SiO₂ mask is removed by ashing with oxygen plasma or by dissolving in an organic solvent such as acetone.

### (Grinding Step)

Semiconductor substrate 10 may be thinned by the grinding step as necessary. In the grinding step, by performing the grinding from the second main surface side of semiconductor substrate 10 on which mask M is formed, the semiconductor layer of semiconductor substrate 10 is thinned. The grinding of the semiconductor layer is generally called back grinding (BG) processing.

Prior to the grinding step, the front surface at mask M side is protected with a protective tape, and the protective tape may be peeled off after the grinding step, as necessary.

For example, the grinding can be performed by polishing the second main surface of semiconductor substrate 10 using abrasive grains. In the grinding, a general condition of the BG processing of the semiconductor substrate can be adopted without particular limitation. The degree of the grinding can be appropriately determined depending on the intended use of the element chip.

In addition, after the grinding step, a polishing step of polishing the second main surface of semiconductor substrate 10 may be performed, as necessary.

### (Holding Step)

In the holding step, the second main surface side of semiconductor substrate 10 is held by holding sheet 22. In this time, it is preferable that holding sheet 22 configures a transfer carrier 20 which is integrated with frame 21. From the viewpoint of handling property, holding sheet 22 is fixed to frame 21.

### (Holding Sheet)

The material of the holding sheet 22 is not particularly limited in the viewpoint of easy attachment of semiconductor substrate 10, it is preferable that holding sheet 22 includes a flexible resin film as adhesion layer 22a and base layer 22b. Holding sheet 22 including the resin film has flexibility.

The thickness (t) of holding sheet 22, for example, is within a range of 50 to 400 μm inclusive, preferably 50 to 300 μm or 50 to 150 μm. Thickness t of holding sheet 22 is the total thickness of adhesion layer 22a and base layer 22b and may be an average value of thicknesses measured at a plurality of arbitrary locations (for example, 10 locations) based on an electron microscopic photograph, or the like.

The material of the resin film is not particularly limited, and examples thereof include a thermoplastic resin such as polyolefins such as polyethylene and polypropylene and polyester such as polyethylene terephthalate. Various additives such as a rubber component (for example, ethylene-propylene rubber (EPM), ethylene-propylene-diene rubber (EPDM), or the like) for applying stretchability, a plasticizer, a softener, an antioxidant, a conductive material, and the like may be blended to the resin film. In addition, the thermoplastic resin may have a functional group that exhibits a photopolymerization reaction such as an acrylic group.

The outer peripheral edge of adhesion layer 22a is adhered to one surface of frame 21 and covers the opening of frame 21. The second main surface of semiconductor substrate 10 is adhered and supported on a portion which is exposed from the opening of frame 21 of adhesion layer 22a. When the plasma process is performed, holding sheet 22 is mounted on the stage such that the stage to be disposed within the plasma processing apparatus is in contact with base layer 22b. That is, the plasma etching is performed from the side of the first main surface located at an opposite side of the second main surface.

As the adhesive for configuring adhesion layer 22a, it is preferable to use the adhesive component in which the adhesive force is reduced by irradiation with an ultraviolet lay (UV). Accordingly, when element chip 110 is picked up after the plasma dicing, element chip 110 is easily peeled off from adhesion layer 22a by performing UV irradiation, element chip 110 is easily picked up. For example, adhesion layer 22a is obtained by applying a UV curable acrylic adhesive on one surface of base layer 22b.

The thickness of adhesion layer 22a is, for example, within a range of 5 to 100 μm inclusive, and preferably 5 to 15 μm.

### (Frame)

Frame 21 to be fixed to holding sheet 22 is a frame body having an opening with an area equal to or larger than the entire area of semiconductor substrate 10 and has a predetermined width and a substantially constant thin thickness. Frame 21 has the rigidity to extent that holding sheet 22 and semiconductor substrate 10 can be transported in a state where holding sheet 22 and semiconductor substrate 10 are held. The shape of the opening of frame 21 is not particularly limited. However, the shape thereof may be a polygon such as a circle, a rectangle, a hexagon, or the like. A notch or a corner cut for positioning may be provided in frame 21. Examples of the material of frame 21 include metals such as aluminum and stainless steel, a resin, or the like.

### (Mounting Step of Semiconductor Substrate (1))

In the mounting step (1), semiconductor substrate 10 is supplied to a processing chamber (reaction chamber) of a vacuum chamber included in the plasma processing apparatus in a case where semiconductor substrate 1.0 is held in holding sheet 22 of transfer carrier 20 as illustrated in FIG. 1, and is mounted on stage 211 within the processing chamber (FIG. 2(1)). In this time, transfer carrier 20 is mounted on stage 211 such that the surface (adhesive surface of adhesion layer 22a), on which semiconductor substrate 10 of holding sheet 22 is held, faces upward.

It is preferable that the thickness of semiconductor substrate 10 to be mounted on the stage is smaller than the width of dividing region R1. In this case, when element chip 110 which is held on holding sheet 22 is transported or element chip 110 which is held on the holding sheet, adjacent side surfaces facing element chip 110 are less likely to collide with each other.

If the width of dividing region R1 is small, adjacent side surfaces facing element chip 110 are easily collide with each other during picking up. In the present exemplary embodiment, by reducing the thickness of semiconductor substrate 10 than the thickness of holding sheet 22, it is possible to reduce the collision between the side surfaces of element chip 110, even when the width of dividing region R1 is small.

A thickness (T) of semiconductor substrate 10 (in particular, the semiconductor layer) is preferably less than 100 μm, and preferably equal to or less than 50 μm or equal to or less than 30 μm. Thickness T of semiconductor substrate 10 (in particular, the semiconductor layer) is, for example, approximately 20 μm. When semiconductor substrate 10 having thickness T is used, it is possible to suppress the tracks and clips generated from the element chip side surface at the time of picking up, even in a case where the flexibility of semiconductor substrate 10 increases.

Thickness T of semiconductor substrate 10 is a thickness of the semiconductor layer and can be measured based on an electron micrograph or the like. Thickness T of semiconductor substrate 10 may be an average value of the thicknesses which are measured for a plurality of arbitrary locations (for example, 10 locations). The width of dividing region R1 can be measured base on the electron micrograph or the like and may be an average value of the widths which are measured for the plurality of arbitrary locations (for example, 10 locations).

### (Plasma Dicing Step (2))

In the plasma dicing step (2), by exposing the first main surface side to plasma in a state where semiconductor substrate 10 is held on holding sheet 22, dividing region R1 is subjected to plasma etching from the first main surface side to the second main surface. By the plasma etching, semiconductor substrate 10 is divided into a plurality of element chips 110 including element regions R2 (FIG. 2(2)).

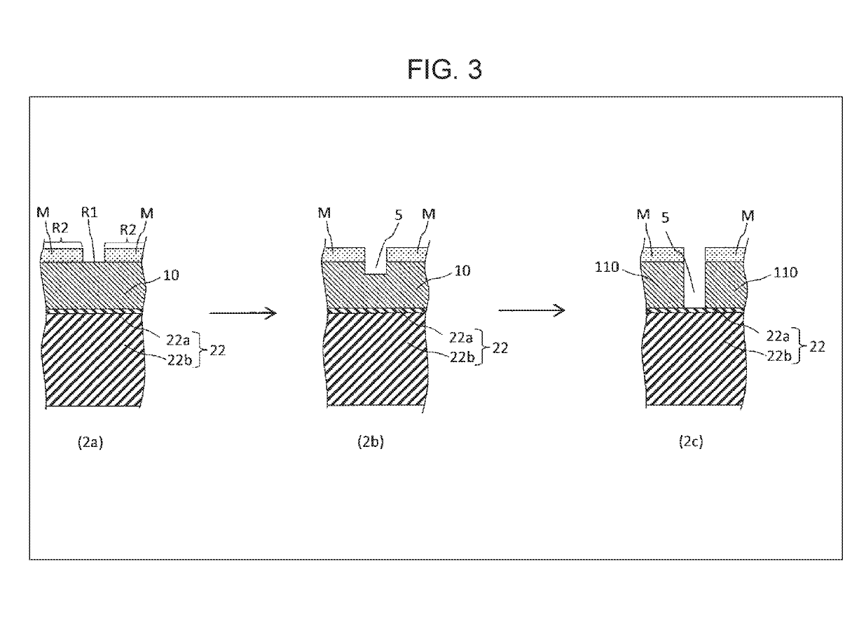

FIG. 3 is a schematic cross-sectional view schematically illustrating a state where the dicing progresses in the plasma dicing step (2). In the plasma dicing step (2), firstly, semiconductor substrate 10 on which mask M is formed on the first main surface is provided to the plasma dicing step (2) (FIG. 3(2a)). When dividing region R1 of semiconductor substrate 10 is exposed, dividing region R1 is subjected to the etching, and groove 5 is formed (FIG. 3(2b)). The etching progresses from the first main surface side to the second main surface While forming groove 5 on dividing region R1 (FIG. 3(2c). In this time, the etching from the first main surface side to the second main surface is performed in a state where the bottom portion of groove 5 is always exposed without covering the bottom portion. Accordingly, semiconductor substrate 10 can be diced into element chip 110 without forming the scallop on the side surface of element chip.

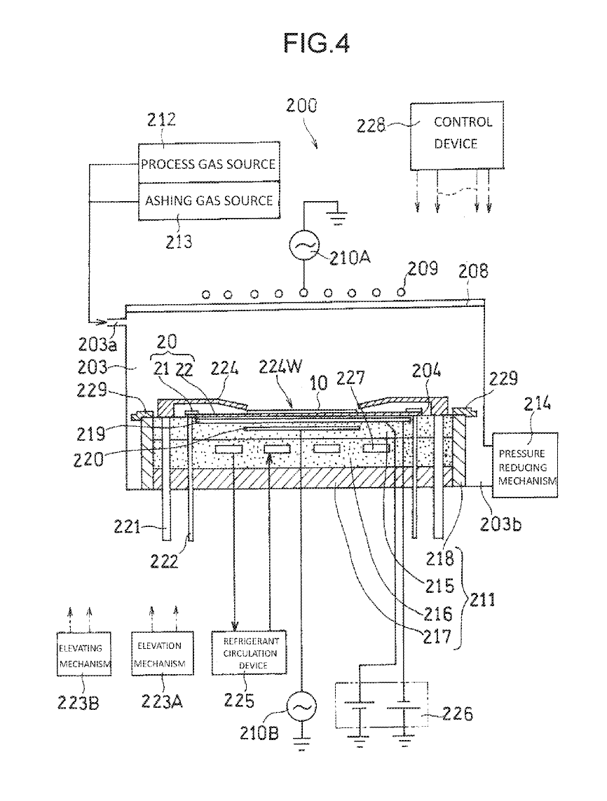

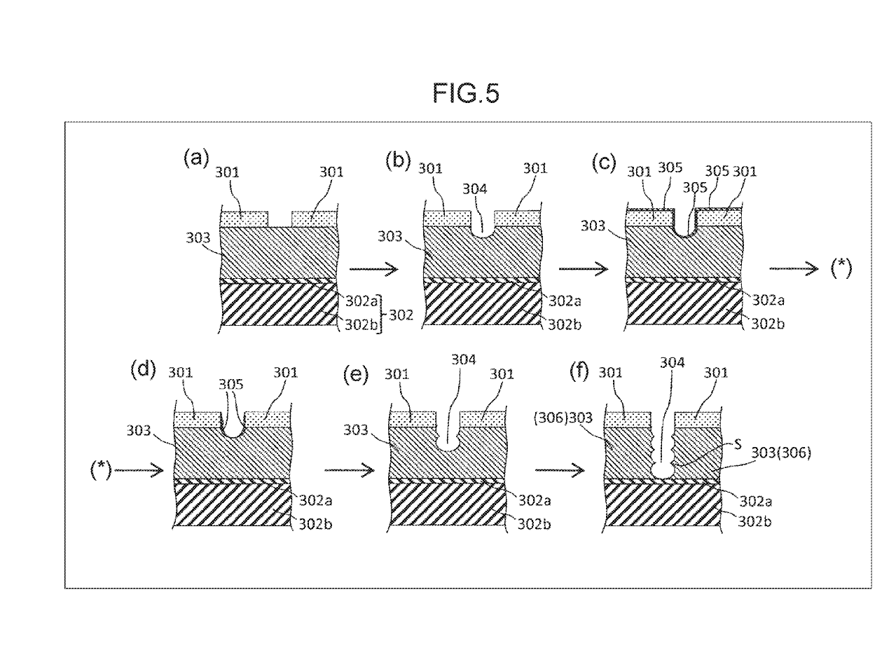

Next, plasma processing apparatus 200 to be used in the plasma dicing step (2) will be described in detail with reference to FIG. 4. However, the plasma processing apparatus is not limited thereto. FIG. 4 is a schematic cross-sectional view schematically illustrating a structure of plasma processing apparatus 200 to be used in the present exemplary embodiment,

Plasma processing apparatus 200 includes stage 211. Transfer carrier 20 is mounted on stage 211 such that the surface (adhesive surface of adhesion layer 22a), on which semiconductor substrate 10 of holding sheet 22 is held, faces upward. Cover 224 having window portion 224W for covering at least a part of frame 21 and holding sheet 22 and for exposing at least a part of semiconductor substrate 10 is disposed above stage 211.

Stage 211 and cover 224 are disposed inside the reaction chamber (vacuum chamber 203). Vacuum chamber 203 has a roughly cylindrical shape with an upper potion opened and the upper opening is closed by dielectric member 208 that is a lid. As a material configuring vacuum chamber 203, aluminum, stainless steel (SUS), aluminum in which the surface is alumite-processed and the like can be exemplified. As the material configuring dielectric member 208, a dielectric material such as yttrium oxide (Y₂O₃), aluminum nitride (AlN), alumina (Al²O₃), quartz (SiO₂), and the like can be exemplified. Antenna 209 as an upper electrode is disposed above dielectric member 208. Antenna 209 is electrically connected to first high frequency power supply 210A. Stage 211 is disposed at the bottom portion side inside vacuum chamber 203.

Gas feed port 203a is connected to vacuum chamber 203. Process gas source 212 and ashing gas source 213 that are a supply source of the process gas is connected to gas feed port 203a respectively; by pipes. In addition, exhaust port 203b is provided on vacuum chamber 203, and pressure reducing mechanism 214 including a vacuum pump for evacuating the gas in vacuum chamber 203 and decompressing the gas is connected to exhaust port 203b.

Stage 211 includes electrode layer 215, metal layer 216, base 217 for supporting, electrode layer 215 and metal layer 216, and outer peripheral portion 218 surrounding electrode layer 215, metal layer 216, and base 217 which have substantially circular shape. Outer peripheral portion 218 is configured of the metal layer with conductivity and etching resistance, and protects electrode layer 215, metal layer 216, and base 217 from the plasma. Annular outer peripheral ring 229 is disposed on the upper surface of outer peripheral portion 218. Outer peripheral ring 229 serves to protect the upper surface of outer peripheral portion 218 from the plasma. Electrode layer 215 and outer peripheral ring 229 are configured of, for example, the above-described dielectric material.

Electrode portion (hereinafter, referred to as an ESC electrode) 219 for configuring electrostatic suction mechanism and high frequency electrode portion 220 which is electrically connected to second high frequency power surface 210B are disposed inside electrode layer 215. Direct-current power supply 226 is electrically connected to ESC electrode 219. The electrostatic suction mechanism is configured of ESC electrode 219 and direct-current power supply 226. The plasma etching may be performed while applying the high frequency power to high frequency electrode portion 220 and applying a bias voltage thereto.

Metal layer 216 is configured of, for example, aluminum in which an alumite coating is formed on the surface thereof. Coolant flow path 227 is formed in metal layer 216. Coolant flow path 227 cools stage 211. By cooling stage 211, holding sheet 22 mounted on stage 211 is cooled and cover 224 in which a part thereof is in contact with stage 211 is also cooled. Accordingly, semiconductor substrate 10 or holding sheet 22 is suppressed from being damaged by being heated during plasma processing. The coolant in coolant flow path 227 is circulated by refrigerant circulation device 225.

A plurality of supporting portions 222 passing through stage 211 is disposed in the vicinity of stage 211. Supporting portion 222 is driven to move up and down by elevation mechanism 223A. When transfer carrier 20 is transported into vacuum chamber 203, transfer carrier 20 is transferred to supporting portion 222 which is raised to a predetermined position. Supporting portion 222 supports frame 21 of transfer carrier 20. The upper end surface of holding sheet 22 descends to the same level as stage 211. Accordingly, transfer carrier 20 is mounted on a predetermined position of stage 211.

A plurality of elevating rods 221 are connected to the end portion of cover 224, thereby capable of elevating cover 224. Elevating rod 221 is driven to move up and down by elevating mechanism 223B. The elevating operation of cover 224 by elevating mechanism 223B can be performed independently of elevation mechanism 223A.

Control device 228 controls an operation of an element for configuring plasma processing apparatus 200 including first high frequency power supply 210A, second high frequency power surface 210B, process gas source 212, ashing gas source 213, pressure reducing mechanism 214, refrigerant circulation device 225, elevation mechanism 223A, elevating mechanism 223B, and the electrostatic suction mechanism.

The plasma is generated under a condition that dividing region R1 is etched. The etching condition can be appropriately selected depending on the material of semiconductor substrate 10. Here, an etching condition in a case where semiconductor substrate 10 is formed of silicon will be exemplified.

In a case where mask M is a resist mask, for example, the etching can be performed under the conditions that the pressure in vacuum chamber 203 is adjusted to 35 Pa, power to be inputted from first high frequency power supply 210A to antenna 209 is set to 3600 W, power to be inputted from second high frequency power surface 210B to high frequency electrode portion 220 is set to 200 W, and the stage temperature is set to −20° C., while supplying 90 seem of sulfur hexafluoride (SF₆), 60 seem of O₂, and 850 seem of He as a raw material.

According to the conditions, semiconductor substrate 10 can be subjected to the etching substantially vertically in the depth direction at a rate of 5 to 10 μm/min with a mask selectivity of about 30. A side wall to be formed by the etching at this time becomes a smooth side wall without the scallop. The seem is a unit of a flow rate and 1 seem is an amount of the gas in a standard state (0° C., 1 atmosphere) flowing 1 cm³ per a minute.

In a case where mask M is a SiO₂ mask, for example, the conditions can be set such that the pressure in vacuum chamber 203 was adjusted to 11 Pa, power to be inputted from first high frequency power supply 210A to antenna 209 is set to 2400 W, power to be inputted from second high frequency power surface 210B to high frequency electrode portion 220 is set to 280 W and the stage temperature is set to −20° C., while supplying 67 seem of SF₆, 33 seem of O₂, 600 seem of He, and 15 seem of SiF₄ as a raw material. According to the above conditions, semiconductor substrate can be subjected to the etching substantially vertically in the depth direction at a rate of 5 to 10 μm/min with the mask selectivity of about 70. A side wall to be formed by the etching at this time becomes a smooth side wall without the scallop.

Since the etching condition has a relatively high mask selectivity of 70, if an oxygen film remains on the front surface of dividing region R1 of semiconductor substrate 10, there is a case where the etching is inhibited. In this case, prior to the etching, an etching (breakthrough) for removing the thin SiO₂ layer having a possibility that the thin SiO₂ remains on the front surface of dividing region R1 of semiconductor substrate 10 may be performed. For example the breakthrough can be performed under the conditions that such that the pressure in vacuum chamber 203 was adjusted to 11 Pa power to be inputted from first high frequency power supply 210A to antenna 209 is set to 2400 W, power to be inputted from second high frequency power surface 210B to high frequency electrode portion 220 is set to 280 W, and the stage temperature is set to −20° C., while supplying 67 seem of SF₆, 33 seem of O₂, and 600 seem of He as a raw material.

In both of the resist mask and the SiO₂ mask the etching condition in which He is used as dilution gas is exemplified. Ar can be used instead of He. However, when using He as the dilution gas, the etching rate is high, the selectivity is great, and perpendicularity of etching shape tends to be favorable.

### (Ashing Step (3))

In a case where mask M is the resist mask, the ashing step (FIG. 2(3)) may be performed after the plasma dicing step (2). In the ashing step (3), mask M may be removed. For example, the ashing step (3) can be performed inside the reaction chamber in which the plasma dicing step is performed in the ashing step (3), while introducing the process gas (for example, oxygen gas) for ashing into the reaction chamber, a predetermined process is maintained in the reaction chamber, the plasma is generated into the reaction chamber by supplying the high frequency power and semiconductor substrate 10 is irradiated with the plasma. By radiating the oxygen plasma, mask M is removed from the front surface of semiconductor substrate 10.

### (Separation (Picking Up) Step (4))

The picking up step (4) is performed after the plasma dicing step (2), or in a case where the ashing step (3) is performed after the plasma dicing step (2), the picking up step (4) is performed after the ashing step (3). Semiconductor substrate 10 which is diced in the plasma dicing step (2) becomes in a state where semiconductor substrate 10 is separated into a state of element chip 110 including element regions 12. Element chip 110 is held on the adhesion surface of adhesion layer 22a of holding sheet 22.

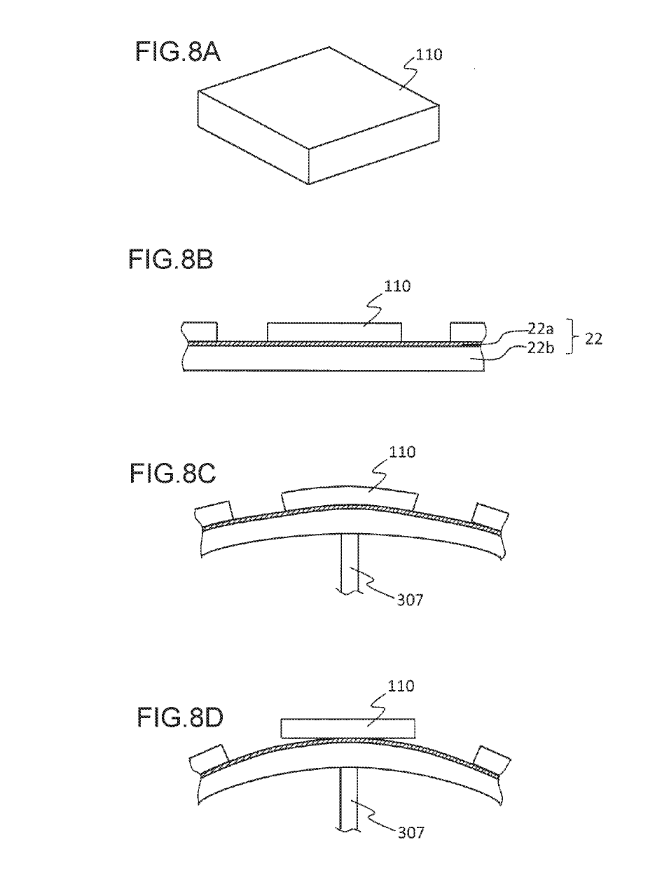

FIGS. 8A to 8D are schematic cross-sectional views schematically illustrating a state of element chip 110 when element chip 110 is picked up from holding sheet 22. In a case where element chip 110 illustrated in FIG. 8A is picked up, firstly, adhesion layer 22a of holding sheet 22 is cured by irradiating holding sheet 22 with a ultraviolet ray, and adhesion between holding sheet 22 and element chip 110 is reduced. By applying tension to holding sheet 22, a. gap between adjacent element chips 110 is expanded, and a region where element chip 110 of holding sheet 22 is held is pushed up with push-up jig 307. Since element chip 110 is thin, the rigidity thereof is poor. Accordingly, when the adhesion remains between holding sheet 22 and element chip 110, the great bending also occurs in element chip 110 as illustrated FIG. 8C. However, since the side, surface of element chip 110 is smooth, the cracks or clips starting from the irregularity in side surface hardly occur. That is, since the scallop as formed by the Bosch method is not formed in the side surface of element chip 110, the element chip is hardly cracked even when element chip 110 is bent in the pickup step (4).

When the pushing up is further performed by push-up jig 307, and the bending becomes greater, as illustrated in FIG. 8D, restoring force of bent element chip 110 exceeds the adhesion force between holding sheet 22 and element chip 110, and element chip 110 is sequentially peeled off from holding sheet 22 inward from the outer edge portion of element chip 110. Thereafter, the top surface of element chip 110 is sucked by the suction head. Accordingly, element chip 110 can be picked up from holding sheet 22.

According to an exemplary embodiment of the present disclosure, cracks or clips in the element chip, which are generated when the element chip which is held on the holding sheet is transported or the element chip is picked up from the holding sheet, can be suppressed. In particular, the manufacturing method according to the disclosure is useful as a method for manufacturing the element chip by plasma dicing from the semiconductor substrate having a small thickness.

What is claimed is:

1. A Method for manufacturing an element chip, comprising:
a mounting step of mounting a semiconductor substrate with flexibility which has a first main surface and a second main surface located at an opposite side of the first main surface, which has a plurality element regions and a dividing region for defining the element regions, and on which a mask for covering the first main surface in each of the elements region and for exposing the first main surface in the dividing region is formed, on a stage which is included in a plasma processing apparatus, in a state where the second main surface is held on a holding sheet; and
a plasma dicing step of dicing the semiconductor substrate into a plurality of element chips including the element regions by exposing a side of the first main surface of the semiconductor substrate to plasma on the stage and etching the semiconductor substrate from the side of the first main surface to the second main surface while forming a groove on the dividing region,
wherein a thickness of the semiconductor substrate is smaller than a thickness of the holding sheet, and
in the plasma dicing step, by performing the etching the semiconductor substrate from the side of the first main surface to the second main surface in a state where a bottom portion of the groove is always exposed, the semiconductor substrate is diced without forming a scallop on a side surface of each of the element chips.

2. The method of claim 1,
wherein the thickness of the semiconductor substrate is 50 μm or less.

3. The method of claim 1,
wherein, in the plasma dicing step, the plasma is generated using a process gas containing sulfur hexafluoride and oxygen, as a raw material.
